(19) United States
(12) Patent Application Publication
(10) Pub. No.: US 2013/0099257 A1
(43) Pub. Date: Apr. 25, 2013

(54) LED PACKAGE WITH EFFICIENT ILLUMINATION

(71) Applicant: Chao- Chuan CHEN, Taichung City (TW)

(72) Inventor: Chao- Chuan CHEN, Taichung City (TW)

(21) Appl. No.: 13/279,336

(22) Filed: Oct. 24, 2011

(51) Int. Cl. H01L 25/075

(52) U.S. Cl. 257/88; 257/E25.019

(57) ABSTRACT

An LED package with efficient illumination includes a base, a plurality of LED chips, an enclosure and an optically transparent plate. The LED chips are placed on the base and are electrically connecting to the base. The enclosure is located on the surface of the base. The LED chips are enclosed by the enclosure. A plurality of grooves is uniformly formed on the surface of the optically transparent plate. A volume of silicone mixed with phosphor powder is injected into each of the grooves. Thus, when packaging the plurality of LED chips, it will reduce the usage amount of the phosphor powder of the optically transparent plate.

### BACKGROUND OF THE INVENTION

1. Field of the Invention

The present invention relates to a LED package, and more particularly to a LED package with efficient illumination.

2. Description of Related Art

Recently, a LED (light emitting diode) with poor emitting power is improved by scientists so that a LED with high emitting power comes to the world. The LED with high emitting power is not only used in some appliance for indicating ON/OFF, but also used in the apparatus for lighting today. The current for the LED with poor emitting power is only about 20 mA, but the current for the LED with high emitting power has arrived more than 2 A. The power of the LED with high emitting power is more than 100 times relative to the LED with poor emitting power. Thus, the illumination of the LED with high emitting power is brighter than the illumination of the 100 pieces of the LEDs with poor emitting power. The illumination of the LED with high emitting power even reaches 160 lumens. Moreover, the advantages such as the lower electricity cost, the compact size, the fast switching speed, the longer lifetime, and the stability . . . etc make the LED with high emitting power be applied widely in the communication field, electronic devices and displaying device.

Referring to the drawing to FIG. 4, a conventional LED package for the LED with high emitting power comprises a base 51, a LED chip 52 and an enclosure 53. The LED chip 52 is placed on the base 51 and is electrically connecting to the base 51. The LED chip 52 is enclosed by the enclosure 53 on the base 51. A filling material is poured into the enclosure 53 and solidified to form a filling lens 54. The filling lens 54 of the conventional LED package is made of the filling material mixed with the phosphor powder for allowing the light form LED chip 52 to be transferred to different color light. One filling lens 54 packages one corresponding LED chip 52. However, the conventional LED package has one shortcoming as following:

The phosphor powder of the filling lens 54 is very expensive, so that when packaging a plurality of LED chips, it will increase much more manufacturing cost because one filling lens 54 corresponds to one LED chip 52.

The present invention has arisen to mitigate and/or obviate the disadvantages of the conventional.

### SUMMARY OF THE INVENTION

The main objective of the present invention is to provide an improved LED package.

To achieve the objective, an LED package with efficient illumination comprises a base, a plurality of LED chips, an enclosure and an optically transparent plate, the LED chips placed on the base and electrically connecting to the base, the enclosure located on the surface of the base, the LED chips enclosed by the enclosure, the optically transparent plate located on the top of the enclosure so that the LED chips are packaged with the optically transparent plate and the enclosure, a plurality of grooves uniformly formed on the surface of the optically transparent plate, a volume of silicone mixed with phosphor powder being injected into each of the grooves, each of the grooves being a trapezoid-shaped groove and the cross-section of the opening of each groove being larger than the cross-section of the bottom of each groove.

Wherein, the silicone mixed with phosphor powder is uniformly arranged on the surface of the optically transparent plate via the grooves so as to efficiently refract the light beams from the LED chips and enlarge a lighting area; one optically transparent plate packages the plurality of LED chips rather than packaging only one LED chip so that when packaging the plurality of LED chips, it will reduce the usage amount of the phosphor powder of the optically transparent plate.

Further benefits and advantages of the present invention will become apparent after a careful reading of the detailed description with appropriate reference to the accompanying drawings.

### BRIEF DESCRIPTION OF THE DRAWINGS

FIG. 1 is an assembled view of an LED package with efficient illumination in accordance with the present invention;

FIG. 2 is a partially enlarged view of the LED package with efficient illumination;

FIG. 3 is a partially enlarged view of the LED package with efficient illumination for showing the light beam from a LED chip refracted by a volume of silicone; and

FIG. 4 is an assembled view of a prior art.

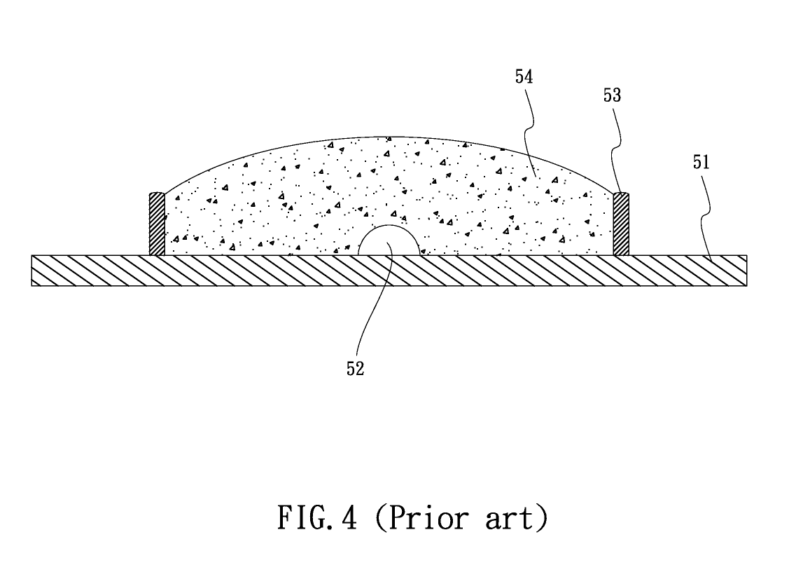

### DETAILED DESCRIPTION OF THE INVENTION

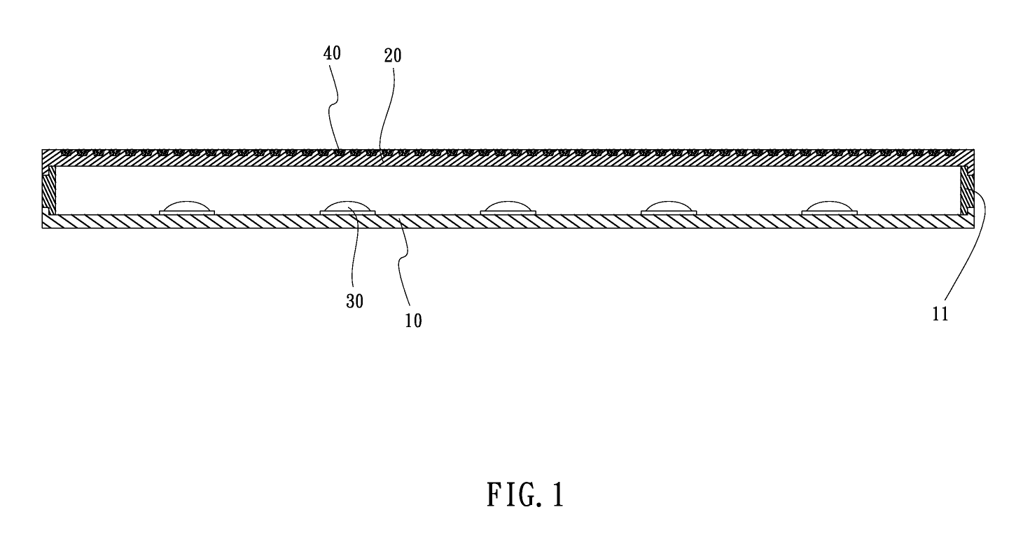

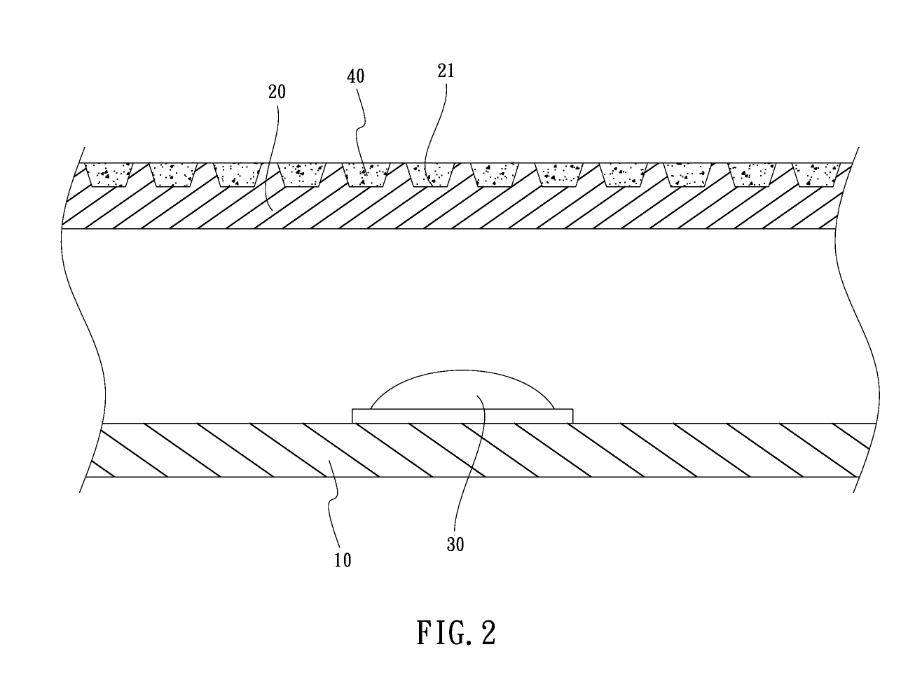

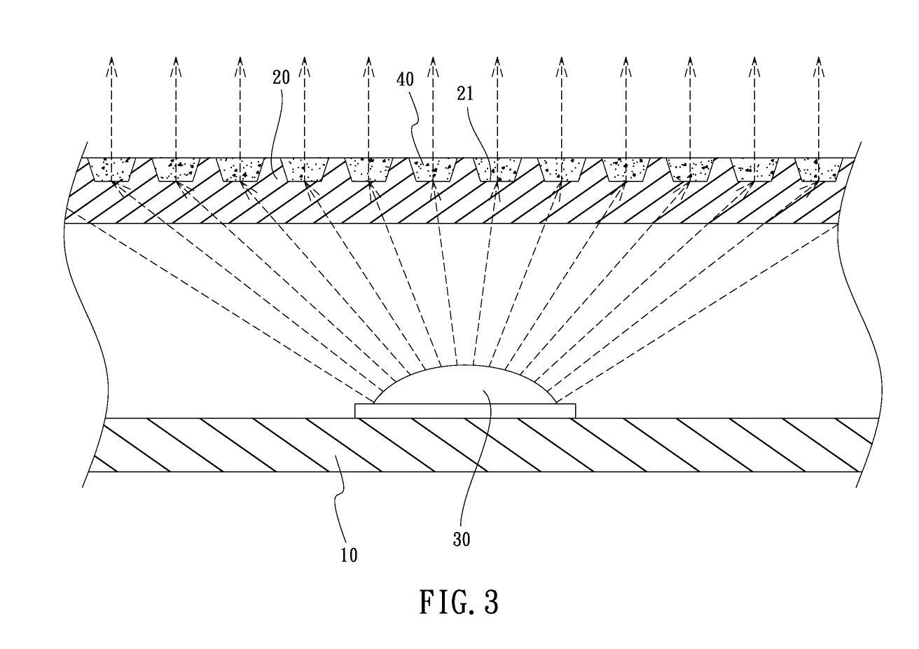

Referring to the drawings to FIGS. 1-2, an LED package with efficient illumination in accordance with the present invention comprises a base 10, a plurality of LED chips 30, an enclosure 11 and an optically transparent plate 20. The LED chips 30 are placed on the base 10 and are electrically connecting to the base 10. The enclosure 11 is located on the surface of the base 10. The LED chips 30 are enclosed by the enclosure 11. The optically transparent plate 20 is mounted on the top of the enclosure 11 so that the LED chips 30 are packaged with the optically transparent plate 20 and the enclosure 11. A plurality of grooves 21 are uniformly formed on the surface of the optically transparent plate 20. A volume of silicone 40 mixed with phosphor powder is injected into each of the grooves 21. Thus, the silicone 40 mixed with phosphor powder is uniformly arranged on the surface of the optically transparent plate 20 via the grooves 21 so as to efficiently refract the light beams from the LED chips 30 and enlarge a lighting area. Referring to the drawing to FIG. 3, the light beams from the LED chips is refracted by the silicone 40 toward the outside area (as the dotted lines with arrow shown in FIG. 3). Under this arrangement, one optically transparent plate 20 packages the plurality of LED chips 30 rather than packaging only one LED chip 30 so that when packaging the plurality of LED chips, it will reduce the usage amount of the phosphor powder of the optically transparent plate 20.

Furthermore, each of the grooves 21 is a trapezoid-shaped groove. The cross-section of the opening of each groove is larger than the cross-section of the bottom of each groove.

Although the invention has been explained in relation to its preferred embodiment, it is to be understood that many other possible modifications and variations can be made without departing from the spirit and scope of the invention as hereinafter claimed.

1. A LED package with efficient illumination comprising:
a base, a plurality of LED chips, an enclosure and an optically transparent plate, the LED chips placed on the base and electrically connecting to the base, the enclosure located on the surface of the base, the LED chips enclosed by the enclosure, the optically transparent plate located on the top of the enclosure so that the LED chips are packaged with the optically transparent plate and the enclosure, a plurality of grooves uniformly formed on the surface of the optically transparent plate, each LED chip corresponding to the corresponding grooves, a volume of silicone mixed with phosphor powder being injected into each of the grooves;
wherein, the silicone mixed with phosphor powder is uniformly arranged on the surface of the optically transparent plate via the grooves so as to efficiently refract the light beams from the LED chips and enlarge a lighting area; one optically transparent plate packages the plurality of LED chips.

2. The LED package with efficient illumination as claimed in claim 1, wherein each of the grooves is a trapezoid-shaped groove and the cross-section of the opening of each groove is larger than the cross-section of the bottom of each groove.
